(19) United States
(12) Patent Application Publication
(10) Pub. No.: US 2010/0328885 A1
(43) Pub. Date: Dec. 30, 2010

(54) Rotatable Cooling Module

(76) Inventors: William H. Scofield, Batavia, IL (US); Lisa M. Valcich, Newburyport, MA (US); Richard A. Garafola, Atkinson, NH (US); Salvatore J. Messana, Morris Plains, NJ (US); Paul M. Rominski, Morris Plains, NJ (US); Peter J. Hayden, Rye, NH (US); Craig E. Schilder, Bolingbrook, IL (US); Nicholas J. Guerra, Oswego, IL (US); Lynn V. Abbott, Aurora, IL (US); Robert M. Wentzel, Elburn, IL (US); Luis M. Diaz, Naperville, IL (US)

Correspondence Address: Alcatel-Lucent USA Inc., Docket Administrator - Room 2F-192, 600-700 Mountain Ave., Murray Hill, NJ, 07974-0636, US

(21) Appl. No.: 12/459,089

(22) Filed: Jun. 26, 2009

(51) Int. Cl. H05K 7/20; F28D 7/02; F28D 15/00

(52) U.S. Cl. 361/695; 165/163; 165/104.34; 361/704; 361/689

(57) ABSTRACT

A rotatable cooling module includes a cooling coil. An input line is coupled to the cooling coil via a coupler that allows the cooling coil to rotate independent of the input line. An output line is coupled to the cooling coil via a second coupler that allows the cooling coil to rotate independent of the output line. A coolant flows through the input line and the first coupler and passes through the cooling coil, which removes heat from an electronic assembly to which the cooling unit is attached. The coolant then flows through the second coupler and through the output line and returns to a heat exchanger, which cools the liquid before recirculating through the cooling unit. The couplers are disposed about a single axis which allows the cooling module to be rotated, and the couplers prevent damage from occurring to any of the elements of the cooling module.

### FIELD OF THE INVENTION

The present invention relates generally to electronic hardware, and more specifically to cooling electronic equipment.

### BACKGROUND OF THE INVENTION

Cooling large concentrations of electronics, as found in telecommunications central offices, server rooms, military installations, etc., is becoming increasingly challenging. Space is often at a premium in these installations, and because of the continuous increase in the power dissipation of modern semiconductors, there is a need to greatly increase the volumetric cooling capacity, often expressed in Watts per liter. If cooling systems are unable to keep up with the expansion of volumetric thermal load, multiple problems are created, including overheated equipment, diminished system reliability, and human factor problems like fan noise and uncomfortably hot maintenance personnel.

One common cooling system for high density electronics is forced air cooling. In forced air cooling systems, fan units internal to the electronic equipment drive cool air from the room through the electronic equipment where the air picks up heat from components and exhausts it back to the room. Air conditioning units located in the room draw in the warm air, cool it using heat exchangers that transfer the heat to a chilled water supply, and return cooled air to the room.

One problem with forced air cooling is that cool air can be mixed with the hot exhaust air. This leads to warm air being blown over the electronic components, making the heat issue even worse. In addition, forced air cooling becomes challenging at thermal densities above a certain limit. Exceeding these limits is not achievable using air as the cooling medium.

One proposal to address the cooling issue is to use fluid cooling in place of high volume forced air cooling. Fluid cooling typically replaces at least some of the airflow with the flow of a fluid coolant or refrigerant that has much higher specific heat, and therefore much higher capacity to remove heat from the air surrounding dense electronics. For example, multiple coolant loops will be installed, where each loop receives cold coolant from a central device, such as a compressor or pumped heat exchanger, and distributes the coolant to cool specific loads. For example, evaporators may be used to cool frames or shelves, or fluid heat sinks to directly cool electronic components. Specialized control systems and coolant distribution apparatus will be needed to manage the complexities of this new fluid cooling regime.

One problem with fluid cooling is that fluid cooling coils are typically fixed. Using fixed cooling equipment makes access to the electronic equipment that is being cooled difficult or often impractical. Therefore access to the cabling side of equipment is difficult, and visual inspection of status light emitting diodes is problematic.

Therefore, a need exists for an efficient and effective way to cool electronic equipment while maintaining access to the electronic equipment.

### BRIEF SUMMARY OF THE INVENTION

An exemplary embodiment of the present invention provides a rotatable cooling module that allows easy access to electronics equipment. By utilizing a single axis of rotation and a pair of liquid-tight couplers, the cooling module is allowed to rotate about the axis while keeping the input (supply) and output (return) cooling lines stationary. Eliminating the axial twist on the input and output cooling lines greatly increases the lifespan of the cooling lines. This leads to a more reliable system that is easier to operate in a more cost-effective manner.

The rotatable cooling module preferably includes a cooling coil (sometimes referred to as an evaporator), a fan unit, an input cooling line, and output cooling line, a first coupler, a second coupler, and a rotational axis about which the cooling module can rotate to allow access to the electronic equipment.

The cooling module is preferably positioned about a central axis so that the cooling module can rotate about the central axis to allow access to the electronic equipment. Pins can be removed from the top and bottom of the cooling module to allow free rotation of the cooling module about the central axis. This allows for access to the electronic equipment without the use of tools and without having to de-install the cooling module.

The input line is connected to a central cooling device, such as a compressor or pumped heat exchanger, and receives cold coolant from the central cooling device and distributes the coolant to cool specific heat loads of air surrounding the electronic equipment.

The input line is coupled to the cooling line via the first coupler, which is positioned about a first axis that is coaxial with the central axis. In an exemplary embodiment, the cooling line includes a bent portion that couples to the first coupler. When the cooling module is rotated about the first axis, the bent portion rotates while the first coupling remains fixed in relation to the cooling line. In this manner, stresses that could damage the cooling line or any associated hoses are reduced or eliminated, thereby greatly extending the life of the cooling line while also increasing the reliability of the cooling module.

The cooling coil is preferably a heat exchanger. Air drawn across the cooling coil is thereby cooled as heat is transferred from the air to the cooling coil and the coolant running through the cooling coil.

Coolant that has absorbed heat while passing through the cooling coil flows through the second coupler and into the output line. This coolant is then passed to the central cooling device, where it is cooled as the heat that the coolant absorbed from the electronic equipment, is dissipated.

The second coupler is preferably positioned about a second axis that is coaxial with the first axis and the central axis. In an exemplary embodiment, the cooling line includes a second bent portion that couples to the second coupler. When the cooling module is rotated about the second axis, the second bent portion rotates while the second coupling remains fixed. In this manner, stresses that could damage the cooling line are reduced or eliminated, thereby greatly extending the life of the cooling line while also increasing the reliability of the cooling module.

Utilizing an exemplary embodiment, the two bent portions remain in a fixed position relative to the cooling coil when the cooling module is rotated. This is accomplished via the first and second couplers, respectively, which allows free rotation of the bent portions.

A fan unit, which can include one or more fans, can be disposed to draw air across the cooling coil. The fan unit preferably draws warm air from the electronic equipment over the cooling coil. This cooled air is then discharged into the ambient environment. In this manner, air in the room that includes the electronic equipment is kept from getting too hot, and the ambient air that is drawn across the electronic equipment is thereby at a lower temperature than it would be without cooling. This provides lower temperatures for the electronic equipment, thereby providing enhanced reliability of the equipment and longer life of the equipment and components.

### BRIEF DESCRIPTION THE SEVERAL VIEWS OF THE DRAWINGS

FIG. 1A depicts a three dimensional view of a cooling module in the closed position in accordance with an exemplary embodiment of the present invention.

FIG. 1B depicts a three dimensional view of a cooling module in the partially open position in accordance with an exemplary embodiment of the present invention.

FIG. 1C depicts a top view of a cooling module in the partially open position in accordance with an exemplary embodiment of the present invention.

FIG. 1D depicts a three dimensional view of a cooling module in the fully open position in accordance with an exemplary embodiment of the present invention.

### DETAILED DESCRIPTION OF THE INVENTION

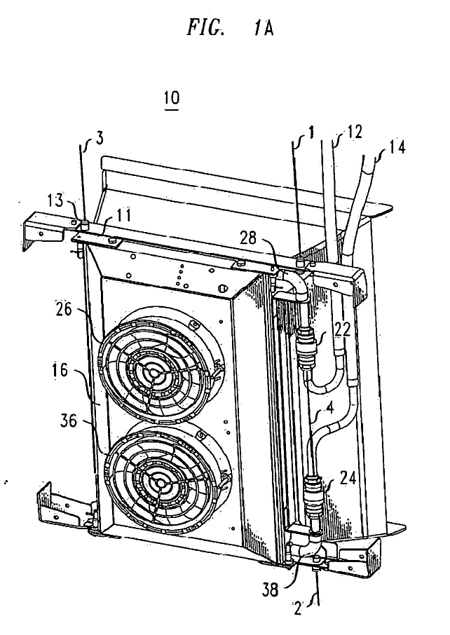

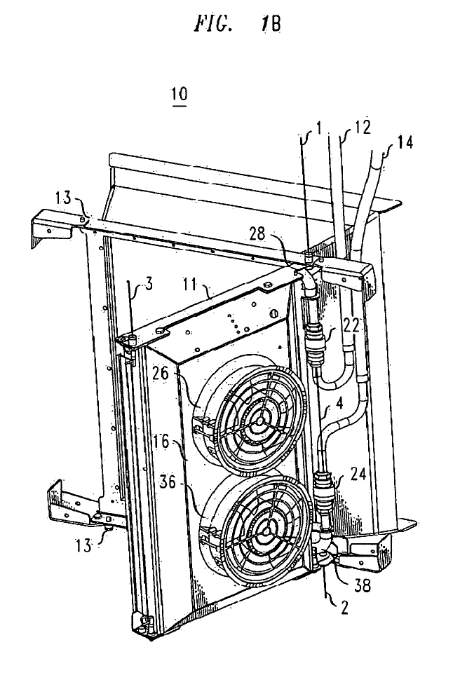

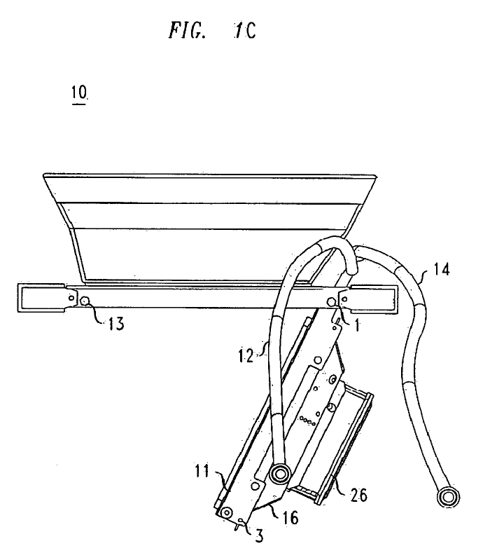

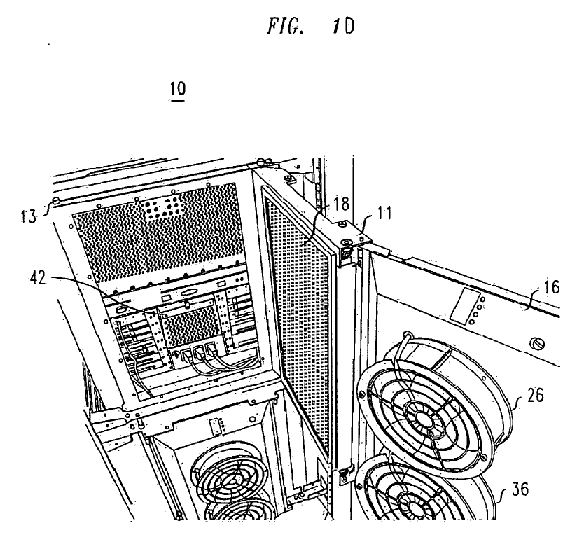

FIGS. 1A-1D depict various views of a cooling module 10 in accordance with an exemplary embodiment of the present invention. FIG. 1A depicts the closed position in which cooling module 10 is disposed to provide cooling to electronic equipment 42 to which cooling module 10 is mounted. FIGS. 1B and 1C depict the open position in which access is provided to electronic equipment 42 to which cooling module 10 is mounted. FIG. 1D depicts the full access position, in which electronic equipment 42 and cooling coil 18 are accessible.

Cooling module 10 comprises cooling line 18, input cooling line 12, output cooling line 14, first coupler 22, second coupler 24, and fan unit 16. In accordance with an exemplary embodiment, cooling module 10 is disposed about axis 4 so that cooling module can rotate about axis 4 to allow access to electronic equipment 42. In an exemplary embodiment, pins 13 are removed from the top and bottom of cooling module 10 to allow free rotation of cooling module 10. This allows for access to electronic equipment 42 without the use of tools and without having to de-install cooling module 10.

Input line 12 is connected to a central cooling device, such as a compressor or pumped heat exchanger. Input line 12 receives cold coolant from the central cooling device and distributes the coolant to cool specific loads of electronic equipment 42.

Input line 12 is coupled to cooling line 18 via first coupler 22. First coupler 22 is disposed about first axis 1, which is coaxial with axis 4. In an exemplary embodiment, cooling line 18 includes a bent portion 28 that couples to first coupler 22. When cooling module 10 is rotated about axis 1, bent portion 28 rotates while first coupling 22 remains fixed. In this manner, stresses that could damage cooling line 18 are reduced or eliminated, thereby greatly extending the life of cooling line 18 while also increasing the reliability of cooling module 10.

In an exemplary embodiment, cooling coil 18 is a heat exchanger. In an alternate exemplary embodiment, cooling coil 18 runs in a serpentine fashion across housing 11, which maximizes the surface area of cooling coil 18. Air drawn across cooling coil 18 is thereby cooled as heat is transferred from the air to cooling coil 18 and the coolant running through cooling coil 18.

Coolant that has absorbed heat while passing through cooling coil 18 in housing 11 flows through second coupler 24 and into output line 14. This coolant is then passed to the central cooling device, where it is cooled and the heat that the coolant absorbed from electronic equipment 42 is dissipated.

Second coupler 24 is preferably disposed about a second axis 2 that is coaxial with first axis 1 and axis 4. In an exemplary embodiment, cooling line 18 includes a bent portion 38 that couples to second coupler 24. When cooling module 10 is rotated about axis 2, bent portion 38 rotates while second coupling 24 remains fixed. In this manner, stresses that could damage cooling line 18 are reduced or eliminated, thereby greatly extending the life of cooling line 18 while also increasing the reliability of cooling module 10.

Utilizing an exemplary embodiment, bent portion 28 and bent portion 38 remain in a fixed position relative to cooling line 18 when cooling module is rotated. This is accomplished via first coupler 22 and second coupler 24, respectively, which allow free rotation of bent portions 28 and 38.

Fan unit 16 is disposed to draw air across cooling coil 18. In this manner, warm air from electronic equipment 42 is cooled as it passes over cooling coil 18. This cooled air is then discharged into the ambient environment. In this manner, air in the room that includes the electronic equipment is kept from getting too hot, and the ambient air that is drawn across the electronic equipment is thereby at a lower temperature than it would be without cooling. This provides lower temperatures for electronic equipment 42, thereby providing enhanced reliability of the equipment and longer life of the equipment and components.

Fan unit 16 can include multiple fans, as is depicted in FIGS. 1A, 1B, and 1D. In these FIGs., fan unit 16 comprises first fan 26 and second fan 36.

While this invention has been described in terms of certain examples thereof, it is not intended that it be limited to the above description, but rather only to the extent set forth in the claims that follow.

We claim:

1. A telecommunications unit comprising:
electronics equipment; and
a rotatable cooling module including a cooling coil axially mounted to the electronics equipment such that the cooling module can be rotated about an axis to provide access to the electronics equipment without disconnecting the cooling coil from the rotatable cooling module.

2. A telecommunications unit in accordance with claim 1, wherein the rotatable cooling module further comprises:
an input line operably coupled to the cooling coil, the input line carrying a cooling fluid to the cooling coil;
an output line operably coupled to the cooling coil, the output line receiving the cooling fluid from the cooling coil;
a first coupler coupling the input line to the cooling coil, the first coupler being disposed on a first axis; and
a second coupler coupling the cooling coil to the output line, wherein the second coupler is disposed along a second axis that is coaxial with the first axis.

3. A telecommunications unit in accordance with claim 2, wherein the position of the first coupler relative to the cooling module changes when the cooling module is rotated about the first axis.

4. A telecommunications unit in accordance with claim 2, wherein the first coupler remains stationary when the cooling module is rotated about the first axis.

5. A telecommunications unit in accordance with claim 2, wherein the position of the second coupler relative to the cooling module changes when the cooling module is rotated about the second axis.

6. A telecommunications unit in accordance with claim 2, the cooling module further comprising a fan disposed to draw air across the cooling coil.

7. A telecommunications unit in accordance with claim 6, wherein the fan is disposed along a third axis, and wherein the third axis is parallel to the first axis.

8. A telecommunications unit in accordance with claim 7, wherein the cooling coil comprises a first face and second face opposite the first face, wherein the second face is adjacent to the fan while in an operating position, and wherein the fan can be rotated about the third axis to provide access to the second face of the cooling coil.

9. A telecommunications unit in accordance with claim, wherein the cooling coil is allowed to rotate independent from the cooling line.

10. A telecommunications unit in accordance with claim 2, wherein the cooling coil comprises a cooling line and a bent portion that is operably coupled to the first coupler, wherein the bent portion and the cooling line remain in a fixed position relative to each other when the cooling module is rotated.

11. A rotatable cooling module comprising:
a cooling coil;
an input line operably coupled to the cooling coil, the input line carrying a cooling fluid to the cooling coil;
an output line operably coupled to the cooling coil, the output line receiving the cooling fluid from the cooling coil;
a first coupler coupling the input line to the cooling coil, the first coupler being disposed on a first axis; and
a second coupler coupling the cooling coil to the output line, wherein the second coupler is disposed along a second axis that is coaxial with the first axis.

12. A cooling module in accordance with claim 11, wherein the position of the first coupler relative to the cooling module changes when the cooling module is rotated about the first axis.

13. A cooling module in accordance with claim 11, wherein the first coupler remains stationary when the cooling module is rotated about the first axis.

14. A cooling module in accordance with claim 11, wherein the position of the second coupler relative to the cooling module changes when the cooling module is rotated about the second axis.

15. A cooling module in accordance with claim 11, wherein the second coupler remains stationary when the cooling module is rotated about the second axis.

16. A cooling module in accordance with claim 11, the cooling module further comprising a fan disposed to draw air across the cooling coil.

17. A cooling module in accordance with claim 16, wherein the fan is disposed along a third axis, and wherein the third axis is parallel to the first axis.

18. A cooling module in accordance with claim 17, wherein the cooling coil comprises a first face and a second face opposite the first face, wherein the second face is adjacent to the fan while in an operating position, and wherein the fan can be rotated about the third axis to provide access to the second lace of the cooling coil.

19. A cooling module in accordance with claim 11, wherein the cooling coil is allowed to rotate independent from the input line.

20. A cooling module in accordance with claim 11, wherein the cooling coil comprises a cooling line and a bent portion that is operably coupled to the first coupler, wherein the bent portion and the cooling line remain in a fixed position relative to each other when the cooling module is rotated.
